(19) United States
(12) Patent Application Publication
(10) Pub. No.: US 2003/0168705 A1
(43) Pub. Date: Sep. 11, 2003

(54) Semiconductor device and method for fabricating the same

(75) Inventors: Yoshiaki Tanida, Kawasaki (JP); Yoshihiro Sugiyama, Kawasaki (JP)

Correspondence Address: ARMSTRONG,WESTERMAN & HATTORI, LLP, 1725 K STREET, NW, SUITE 1000, WASHINGTON, DC, 20006, US

(73) Assignee: FUJITSU LIMITED, Kawasaki (JP)

(21) Appl. No.: 10/359,212

(22) Filed: Feb. 6, 2003

(30) Foreign Application Priority Data
Mar. 7, 2002 (JP) 2002-061254

(51) Int. Cl. H01L 29/76

(52) U.S. Cl. 257/410

(57) ABSTRACT

A semiconductor device in which a gate insulator is formed by the use of a high-dielectric-constant material to keep its interface state density low and a method for fabricating such a semiconductor device. Before a gate electrode being formed, a layer of aluminum oxide, being a gate insulator, is doped with nitrogen from the interface between the layer of aluminum oxide and a semiconductor substrate or from the interface between the layer of aluminum oxide and the gate electrode to form the gate insulator including a nitrided area which extends from the interface. Then a layer of polycrystalline silicon or polycrystalline silicon germanium is formed on the gate insulator including a nitrided area to form the gate electrode. This decreases interface state density at the interface between the gate insulator and the semiconductor substrate. Moreover, this prevents boron penetration which has conventionally been caused by annealing treatment performed for forming the gate electrode, a source, and a drain, so the interface state density is kept low.

### CROSS-REFERENCE TO RELATED APPLICATIONS

This application is based upon and claims priority of Japanese Patent Application No. 2002-061254, filed on Mar. 7, 2002, the contents being incorporated herein by reference.

### BACKGROUND OF THE INVENTION

(1) Field of the Invention

This invention relates to a semiconductor device and a method for fabricating such a semiconductor device and, more particularly, to a semiconductor device of metal oxide semiconductor (MOS) structure including a gate insulator of a high-dielectric-constant material, such as aluminum oxide (AL₂O₃), and a method for fabricating such a semiconductor device.

(2) Description of the Related Art

Conventionally, silicon dioxide (SiO₂), being a low-dielectric-constant material, has widely been used for forming gate insulators in semiconductor devices, such as logic circuits, random access memories (RAMs), and erasable programmable read only memories (EPROMs), of MOS structure.

In recent years the processing speeds of these devices of MOS structure have improved and they have become minuter. With these tendencies gate insulators formed in them have become thinner. As a result, boron (B) introduced into gate electrodes on p-channel MOS transistors (pMOS) may penetrate through gate insulators to semiconductor substrates due to annealing treatment performed in the process of fabrication. This is what is called boron penetration. Moreover, gate insulators have become thinner, so various other problems, such as an increase in a leakage current and degradation in the ability to withstand stress, have also arisen.

Methods in which a high-dielectric-constant material is used for forming a gate insulator have also been proposed from the viewpoint of preventing boron penetration and a leakage current by increasing the physical thickness of a gate insulator. However, some of these high-dielectric-constant materials crystallize at the time of annealing treatment and cause an increase in a leakage current. Therefore, in recent years the use of aluminum oxide which shows comparatively good thermostability has been discussed. Furthermore, it is hoped that aluminum oxide will be able to decrease interface state density at the interface between a semiconductor substrate and gate insulator.

However, if aluminum oxide is used for forming a gate insulator, the interface state density is not sufficient low compared with a case where silicon dioxide is used. That is to say, it is difficult to obtain much the same interface state density that is obtained by the use of silicon dioxide.

Moreover, even if aluminum oxide is used for forming a gate insulator, boron penetration will occur due to annealing treatment performed in the process of the fabrication of a semiconductor device. As a result, the interface state density may become extremely high.

### SUMMARY OF THE INVENTION

The present invention was made under the background circumstances as described above. An object of the present invention is to provide a semiconductor device with a gate insulator formed by the use of a high-dielectric-constant material which has low interface state density at an interface between the gate insulator and a semiconductor substrate and a method for fabricating such a semiconductor device.

In order to achieve the above object, a semiconductor device including a p-channel MOS transistor is provided. This semiconductor device comprises a semiconductor substrate on which a source and a drain are formed, a gate insulator formed on the semiconductor substrate by the use of a high-dielectric-constant material including a nitrided area, and a gate electrode formed on the gate insulator.

Furthermore, in order to achieve the above object, a method for fabricating a semiconductor device including a p-channel MOS transistor is provided. This method comprises the steps of forming a gate insulator on a semiconductor substrate by nitriding a high-dielectric-constant material, depositing a material for forming a gate electrode on the gate insulator formed, and implanting boron ions in the deposited material for forming a gate electrode and areas in the semiconductor substrate which form a source and a drain and performing annealing treatment.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 is a sectional view of a pMOS.

FIG. 2 is a simplified sectional view of a MOS capacitor.

FIG. 3 is a graph showing results obtained by measuring the conductance of a MOS capacitor where an insulating film is doped with nitrogen from the interface between the insulating film and a silicon substrate.

FIG. 4 is a graph showing results obtained by measuring the conductance of a MOS capacitor where an insulating film is doped with nitrogen from the interface between the insulating film and an electrode.

### DESCRIPTION OF THE PREFERRED EMBODIMENTS

Embodiments of the present invention will now be described with reference to the drawings.

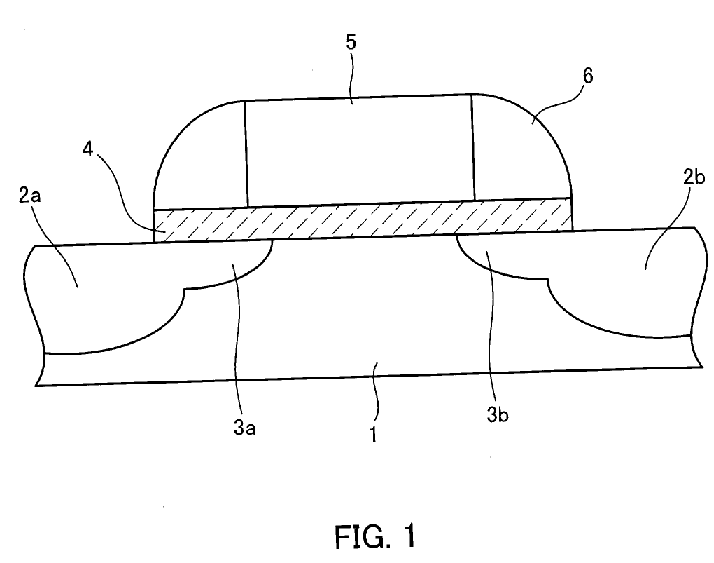

FIG. 1 is a sectional view of a pMOS. A pMOS shown in FIG. 1 includes a source 2a, a drain 2b, and extensions 3a and 3b formed on a semiconductor substrate 1, such as a silicon substrate.

A gate insulator 4 of a high-dielectric-constant material including a nitrided area is formed on the semiconductor substrate 1. Aluminum oxide or a material largely composed of aluminum oxide can be used as a high-dielectric-constant material for forming the gate insulator 4. Lithium oxide (Li₂O), beryllium oxide (BeO), magnesium oxide (MgO), calcium oxide (CaO), strontium oxide (SrO), scandium oxide (Sc₂O₃), yttrium oxide (Y₂O₃), lanthanum oxide (La₂O₃), thorium oxide (ThO₂), uranium dioxide (UO₂), zirconium oxide (ZrO₂), hafnium oxide (HfO₂), praseodymium oxide (Pr₂O₃), neodymium oxide (Nd₂O₃), or the like can be used in place of aluminum oxide.

A high-dielectric-constant material used may be a material largely composed of one, such as aluminum oxide or hafnium oxide, of the above materials or a material composed of two or more of the above materials. If a material is selected, interface state density at an interface between the gate insulator 4 formed by the use of the material and the semiconductor substrate 1 and other characteristics necessary for semiconductor devices to be fabricated will be taken into consideration.

A gate electrode 5 is formed on the gate insulator 4 formed on the semiconductor substrate 1 by using polycrystalline silicon or polycrystalline silicon germanium as a material. A side wall 6 is formed on the side of the gate electrode 5.

The pMOS of the above structure is formed in the following way. The gate insulator 4 is formed first on the semiconductor substrate 1. To form the gate insulator 4, a layer of aluminum oxide of a thickness of several nanometers is formed by the use of a thin film deposition system, such as a chemical vapor deposition (CVD) system. In this case, the layer of aluminum oxide is doped with nitrogen from the interface between the layer of aluminum oxide and the semiconductor substrate 1. As a result, an area in the gate insulator 4 which extends from the interface between the gate insulator 4 and the semiconductor substrate 1 is nitrided. That is to say, a nitrided area is formed in the gate insulator 4. Polycrystalline silicon or polycrystalline silicon germanium is deposited on the layer of aluminum oxide. The thickness of a layer of polycrystalline silicon or polycrystalline silicon germanium formed is between, for example, several ten and several hundred nanometers. Alternatively, to form the gate insulator 4, the layer of aluminum oxide is doped with nitrogen from the interface between the layer of aluminum oxide and the layer of polycrystalline silicon or polycrystalline silicon germanium. As a result, an area in the gate insulator 4 which extends from the interface between the gate insulator 4 and the layer of polycrystalline silicon or polycrystalline silicon germanium is nitrided. That is to say, a nitrided area is formed in the gate insulator 4.

Next, a predetermined resist pattern is formed after the formation of a layer of resist, exposure treatment, and development treatment. The layer of polycrystalline silicon or polycrystalline silicon germanium and the gate insulator 4 beneath it are etched.

Then the layer of resist is removed and boron, being an impurity, is implanted in the layer of polycrystalline silicon or polycrystalline silicon germanium and the semiconductor substrate 1 in the form of ions in a predetermined dosage. For example, implantation energy is between several and several ten kiloelectron-volts and a dosage is between 1×10¹⁵ and 5×10¹⁵ cm⁻².

Finally, to activate the boron ions implanted, annealing treatment is performed, for example, at a temperature of about 900° C. for at least ten seconds. As a result, the source 2a, drain 2b, and gate electrode 5 are formed. The extensions 3a and 3b can be formed by the well-known disposal side wall process or the like.

Now, interface state density at the interface between the gate insulator 4 including a nitrided area and the semiconductor substrate 1 will be discussed.

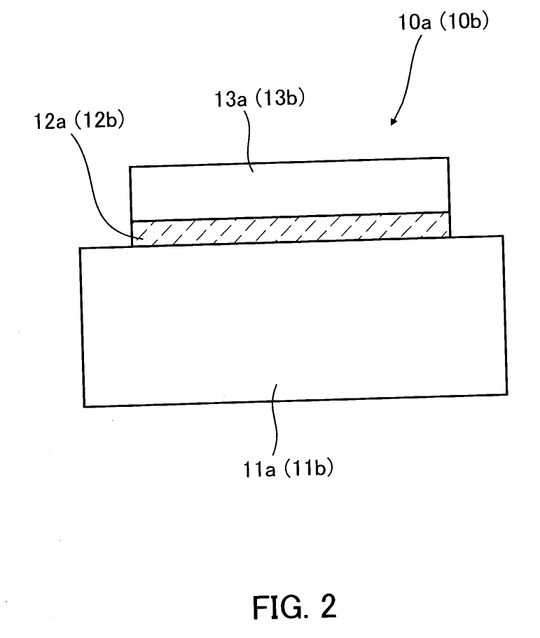

FIG. 2 is a simplified sectional view of a MOS capacitor.

A MOS capacitor 10a is formed in the following way. A silicon substrate 11a is cleaned first with chemicals so that part of the surface of the silicon substrate 11a will get exposed. Then a layer of aluminum oxide of a thickness of several nanometers is formed with a CVD system. When this layer of aluminum oxide is formed, the layer of aluminum oxide is doped with nitrogen from the interface between the layer of aluminum oxide and the silicon substrate 11a. As a result, an insulating film 12a including a nitrided area which extends from the interface between the layer of aluminum oxide and the silicon substrate 11a is formed. A layer of polycrystalline silicon or polycrystalline silicon germanium is formed on the insulating film 12a. And finally, boron ions are implanted in the layer of polycrystalline silicon or polycrystalline silicon germanium and the silicon substrate 11a in a predetermined dosage and annealing treatment is performed at a temperature of 900° C. for at least ten seconds. As a result, an electrode 13a is formed on the insulating film 12a.

Now, interface state density at the interface between the insulating film 12a and the silicon substrate 11a in the MOS capacitor 10a of the above structure will be evaluated by a conductance method. Measurements are made with gate voltage applied between the electrode 13a and the silicon substrate 11a. Under this conductance method, the value of a conductance peak which will appear at a gate voltage of about 1 volt is proportional to interface state density at the interface between the silicon substrate 11a and the insulating film 12a.

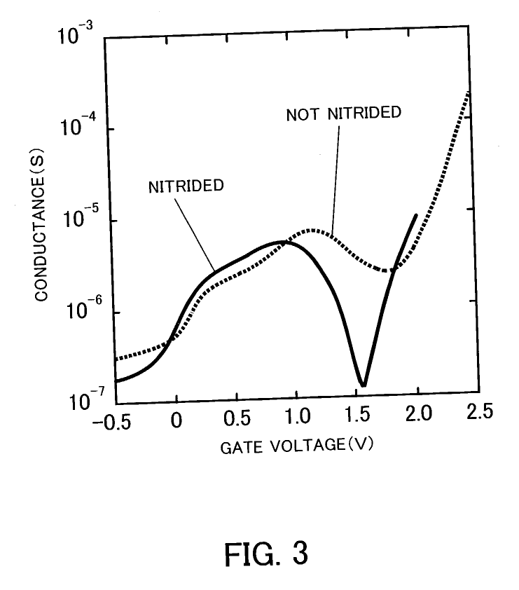

FIG. 3 is a graph showing results obtained by measuring the conductance of the MOS capacitor 10a where the insulating film 12a is doped with nitrogen from the interface between the insulating film 12a and the silicon substrate 11a. Horizontal and vertical axes in FIG. 3 express gate voltage (V) and conductance (S) respectively. In FIG. 3, results obtained by measuring the conductance of the MOS capacitor 10a where the insulating film 12a includes a nitrided area are shown by a solid line and results obtained by measuring the conductance of the MOS capacitor 10a where the insulating film 12a does not include a nitrided area are shown by a dashed line.

As can be proved by the results shown in FIG. 3, if the insulating film 12a does not include a nitrided area, a conductance peak appears at a gate voltage of about 1 volt, and then the conductance decreases slightly with an increase in the gate voltage. On the other hand, if the insulating film 12a includes a nitrided area, a conductance peak appears at a gate voltage of about 1 volt, and then the conductance decreases drastically with an increase in the gate voltage. The value of a conductance peak which appears at this time is smaller than that of a conductance peak which appears in the case of the insulating film 12a not including a nitrided area. Therefore, by doping nitrogen to the insulating film 12a from the interface between the insulating film 12a and the silicon substrate 11a and forming a nitrided area in the insulating film 12a, interface state density at the interface between the silicon substrate 11a and the insulating film 12a can be decreased.

A case where the insulating film 12a is doped with nitrogen from the interface between the insulating film 12a and the silicon substrate 11a to form a nitrided area in the insulating film 12a has been described. Now, a case where an insulating film is doped with nitrogen from the interface between the insulating film and an electrode to form a nitrided area in the insulating film will be described.

In this case, a MOS capacitor 10b shown in FIG. 2 is formed in the following way. A silicon substrate 11b is cleaned first with chemicals so that part of the surface of the silicon substrate 11b will get exposed. Then a layer of aluminum oxide of a thickness of several nanometers is formed with a CVD system. The layer of aluminum oxide is nitrided to form an insulating film 12b. Then a layer of polycrystalline silicon or polycrystalline silicon germanium is formed on the insulating film 12b. And finally, boron ions are implanted in the layer of polycrystalline silicon or polycrystalline silicon germanium in a predetermined dosage and annealing treatment is performed at a temperature of 900° C. for at least ten seconds. As a result, an electrode 13b is formed on the insulating film 12b.

Now, interface state density at the interface between the insulating film 12b and the silicon substrate 11b in the MOS capacitor 10b of the above structure will be evaluated by a conductance method. Measurements are made in the same way as that used for evaluating the above MOS capacitor 10a.

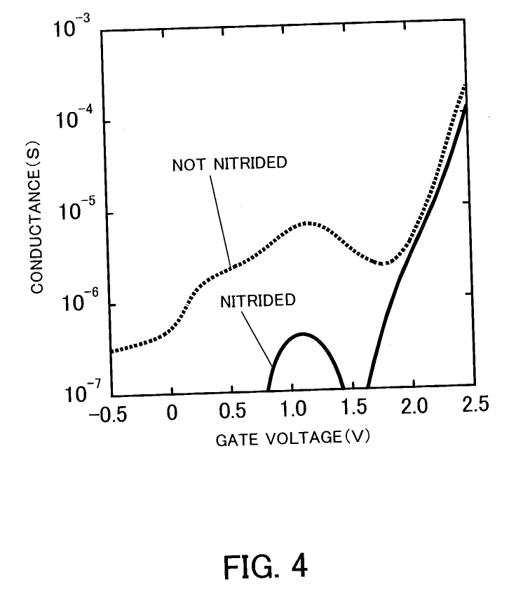

FIG. 4 is a graph showing results obtained by measuring the conductance of the MOS capacitor 10b where the insulating film 12b is doped with nitrogen from the interface between the insulating film 12b and the electrode 13b. Horizontal and vertical axes in FIG. 4 express gate voltage (V) and conductance (S) respectively. In FIG. 4, results obtained by measuring the conductance of the MOS capacitor 10b where the insulating film 12b includes a nitrided area are shown by a solid line and results obtained by measuring the conductance of the MOS capacitor 10b where the insulating film 12b does not include a nitrided area are shown by a dashed line.

As can be proved by the results shown in FIG. 4, if the insulating film 12b does not include a nitrided area, a conductance peak appears at a gate voltage of about 1 volt, and then the conductance decreases slightly with an increase in the gate voltage. This is the same with the results shown in FIG. 3. On the other hand, if the insulating film 12b includes a nitrided area, the value of a conductance peak which appears at a gate voltage of about 1 volt is very small, compared with a case where the insulating film 12b does not include a nitrided area. Therefore, by doping nitrogen to the insulating film 12b from the interface between the insulating film 12b and the electrode 13b and forming a nitrided area in the insulating film 12b, interface state density at the interface between the silicon substrate 11b and the insulating film 12b can be decreased drastically.

The method of doping nitrogen described above can be performed by using nitrogen gas or gas including nitrogen as a component or by implanting nitrogen ions or ion species including nitrogen as a component. Under the ion implantation method, nitrogen can be introduced without making a surface rough, compared with the method using gas. Another method that can nitride a high-dielectric-constant material, such as the above aluminum oxide or material including aluminum oxide, may be used as a method for introducing nitrogen.

On the basis of the results obtained by measuring the conductance of the MOS capacitors 10a and 10b, the layer of aluminum oxide is doped with nitrogen from the interface between the layer of aluminum oxide and the semiconductor substrate 1 or from the interface between the layer of aluminum oxide and the gate electrode 5 to form the gate insulator 4 including a nitrided area which extends from the interface if a pMOS having the structure shown in FIG. 1 is fabricated. This can decrease interface state density at the interface between the semiconductor substrate 1 and the gate insulator 4 compared with conventional cases where silicon dioxide is used for forming a gate insulator. Moreover, this prevents boron penetration, that is to say, the movement of boron in the gate electrode 5 to the semiconductor substrate 1, which has conventionally been caused by annealing treatment performed for forming the gate electrode 5, and prevents an increase in the interface state density.

The above method for fabricating a pMOS is applicable to a semiconductor device of a complementary metal oxide semiconductor (CMOS) type in which an n-channel MOS transistor (nMOS), together with a pMOS, is formed. In this case, a gate insulator in an nMOS may be formed with the gate insulator 4 in the pMOS shown in FIG. 1 or may be formed separately from it. Furthermore, a gate insulator in an nMOS and the gate insulator 4 in the pMOS shown in FIG. 1 may differ in material. If a gate insulator in an nMOS includes a nitrided area, interface state density at the interface between the semiconductor substrate 1 and the gate insulator can be decreased. This is the same with the gate insulator 4 in the pMOS. With a semiconductor device of a CMOS type having the above structure, interface state density both in a pMOS and in an nMOS can be kept low, so the performance and reliability of the semiconductor device will be improved. The performance and reliability of an integrated circuit in which such a semiconductor device is formed will also be improved.

As described above, the gate insulator 4 is doped with nitrogen from the interface between the gate insulator 4 and the semiconductor substrate 1 or from the interface between the gate insulator 4 and the gate electrode 5. However, the gate insulator 4 may be doped with nitrogen both from the interface between the gate insulator 4 and the semiconductor substrate 1 and from the interface between the gate insulator 4 and the gate electrode 5. As a result, the gate insulator 4 formed includes a nitrided area which extends from the interface between the gate insulator 4 and the semiconductor substrate 1 and a nitrided area which extends from the interface between the gate insulator 4 and the gate electrode 5. The interface state density therefore can stably be kept low.

Moreover, to form the gate insulator 4 on the semiconductor substrate 1, aluminum silicon nitride may be used in place of a material, such as one including the above aluminum oxide, which needs to be nitrided. In this case, the gate insulator 4 is formed on the semiconductor substrate 1 by the use of aluminum silicon nitride. Then a material for forming the gate electrode 5 is deposited on the gate insulator 4. Then boron ions are implanted in the material for forming the gate electrode 5 and the semiconductor substrate 1. After that annealing treatment is performed, for example, at a temperature of 900° C. for at least ten seconds to form the gate electrode 5, source 2a, and drain 2b. As a result, a pMOS is formed. Therefore, there is no need to dope nitrogen for nitriding and the gate insulator 4 can be formed efficiently. Moreover, with a semiconductor device of a CMOS type an nMOS can be formed in the same way that is used for forming a pMOS.

As has been described in the foregoing, in the present invention a gate insulator is formed on a semiconductor substrate by the use of a high-dielectric-constant material including a nitrided area. Therefore, interface state density at the interface between the gate insulator and the semiconductor substrate can be kept low, resulting in an improvement in the performance and reliability of a semiconductor device.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A semiconductor device including a p-channel MOS transistor, the device comprising:
a semiconductor substrate on which a source and a drain are formed;
a gate insulator formed on the semiconductor substrate by the use of a high-dielectric-constant material including a nitrided area; and
a gate electrode formed on the gate insulator.

2. The semiconductor device according to claim 1, wherein the high-dielectric-constant material is a material including at least one selected from a group of aluminum oxide, lithium oxide, beryllium oxide, magnesium oxide, calcium oxide, strontium oxide, scandium oxide, yttrium oxide, lanthanum oxide, thorium oxide, uranium dioxide, zirconium oxide, hafnium oxide, praseodymium oxide, and neodymium oxide.

3. The semiconductor device according to claim 1, wherein the nitrided area extends from one interface of the gate insulator.

4. The semiconductor device according to claim 1, wherein a material for forming the gate electrode is polycrystalline silicon or polycrystalline silicon germanium.

5. The integrated circuit including the semiconductor device according to claim 1.

6. A method for fabricating a semiconductor device including a p-channel MOS transistor, the method comprising the steps of:
forming a gate insulator on a semiconductor substrate by nitriding a high-dielectric-constant material;
depositing a material for forming a gate electrode on the gate insulator formed; and
implanting boron ions in the deposited material for forming a gate electrode and areas in the semiconductor substrate which form a source and a drain, and performing annealing treatment.

7. The method for fabricating a semiconductor device according to claim 6, wherein the high-dielectric-constant material is a material including at least one selected from a group of aluminum oxide, lithium oxide, beryllium oxide, magnesium oxide, calcium oxide, strontium oxide, scandium oxide, yttrium oxide, lanthanum oxide, thorium oxide, uranium dioxide, zirconium oxide, hafnium oxide, praseodymium oxide, and neodymium oxide.

8. The method for fabricating a semiconductor device according to claim 6, wherein the annealing treatment is performed at a temperature of about 900° C. for at least ten seconds.

9. The method for fabricating a semiconductor device according to claim 6, wherein when the high-dielectric-constant material is nitrided to form the gate insulator, the high-dielectric-constant material is nitrided by the use of nitrogen gas or gas including nitrogen as a component.

10. The method for fabricating a semiconductor device according to claim 6, wherein when the high-dielectric-constant material is nitrided to form the gate insulator, the high-dielectric-constant material is nitrided by implanting nitrogen ions or ion species including nitrogen as a component.

11. A method for fabricating a semiconductor device including a p-channel MOS transistor, the method comprising the steps of:
forming a gate insulator of a material including aluminum silicon nitride on a semiconductor substrate;
depositing a material for forming a gate electrode on the gate insulator formed; and
implanting boron ions in the deposited material for forming a gate electrode and areas in the semiconductor substrate which form a source and a drain, and performing annealing treatment.

12. The method for fabricating a semiconductor device according to claim 11, wherein the annealing treatment is performed at a temperature of about 900° C. for at least ten seconds.
